(19) United States
(12) Patent Application Publication
(10) Pub. No.: US 2007/0120468 A1
(43) Pub. Date: May 31, 2007

(54) DISPLAY APPARATUS AND METHOD OF MANUFACTURING THE SAME

(75) Inventors: Sung-Soo LEE, Suwon-si (KR); Jae-Hoon JUNG, Suwon-si (KR); Un-Cheol SUNG, Anyang-si (KR); Ji-Hye CHOI, Busan-city (KR)

Correspondence Address: H.C. PARK & ASSOCIATES, PLC, 8500 LEESBURG PIKE, SUITE 7500, VIENNA, VA, 22182, US

(73) Assignee: SAMSUNG ELECTRONICS CO., LTD., Suwon-si (KR)

(21) Appl. No.: 11/556,610

(22) Filed: Nov. 3, 2006

(30) Foreign Application Priority Data
Nov. 30, 2005 (KR) 10-2005-0115884

(51) Int. Cl. H01L 51/00

(52) U.S. Cl. 313/504

(57) ABSTRACT

The present invention discloses a display apparatus including: an insulating substrate, a metal film formed on a first surface of the insulating substrate and comprising a magnetic substance, a thin film transistor formed on a second surface of the insulating substrate, a first passivation film formed on the thin film transistor, a pixel electrode electrically connected with the thin film transistor and forming a pixel region, an organic layer formed on the pixel electrode, and a common electrode formed on the organic layer.

### CROSS-REFERENCE TO RELATED APPLICATIONS

This application claims priority from and the benefit of Korean Patent Application No. 2005-0115884, filed on Nov. 30, 2005, which is hereby incorporated by reference for all purposes as if fully set forth herein.

### BACKGROUND OF THE INVENTION

1. Field of the Invention

The present invention relates to a display apparatus and a method of manufacturing the same, and more particularly, to a display apparatus that may prevent an insulating substrate from sagging in a manufacturing process, and a method of manufacturing the same.

2. Discussion of the Background

There are various display apparatuses such as liquid crystal displays (LCD), plasma display panels (PDP), etc. Among various display apparatuses, an organic light emitting diode (OLED) has recently attracted attention because it is driven with a low voltage, is thin and light, has a wide viewing angle, has a relatively short response time, etc.

Such an OLED may be a passive matrix or an active matrix device according to its driving method. Further, the OLED may be a low molecular weight OLED or a polymer OLED according to the molecular weight of an organic layer, such as a hole injecting layer (HIL) and an emission layer (EML).

Meanwhile, a thermal evaporation method may be employed to form an organic layer of the low molecular weight OLED. Before forming the organic layer, a manufacturing process may be performed in which the parts of the display apparatus where the organic layer is to be deposited face upward. On the other hand, while the organic layer is being formed by the thermal evaporation method, the display apparatus is placed above a deposition source, and the parts where the organic layer is to be deposited face down toward the deposition source. For this, the display apparatus is turned upside down.

Nowadays, large display apparatuses are much in demand. However, when a large display apparatus is turned upside down, the center of the insulating substrate may sag. Therefore, the organic layer is not uniformly deposited throughout the insulating substrate, so that the display apparatus may be defective. Further, when a plastic substrate is utilized as the insulating substrate, the sagging problem may be worse. Likewise, this problem may arise when a common electrode is formed on the organic layer by thermal evaporation.

To solve the sagging problem, a display apparatus may be disposed and fastened between a substrate supporter, made of a magnetic substance, and a magnet attracting the substrate supporter and is then turned upside down to thereby form the organic layer or/and the common electrode. However, sagging of the insulating substrate may still occur when using the magnet and the substrate supporter.

### SUMMARY OF THE INVENTION

The present invention provides a display apparatus that may effectively prevent an insulating substrate from sagging in a manufacturing process.

The present invention also provides a display apparatus manufacturing method that may effectively prevent an insulating substrate from sagging in the manufacturing process.

Additional aspects and/or advantages of the present invention will be set forth in part in the description which follows and, in part, will be obvious from the description, or may be learned by practice of the present invention.

The present invention discloses a display apparatus including an insulating substrate, a metal film formed on a first surface of the insulating substrate, a thin film transistor formed on a second surface of the insulating substrate, a first passivation film formed on the thin film transistor, a pixel electrode formed on the passivation film electrically connected with the thin film transistor and forming a pixel region, an organic layer formed on the pixel electrode, and a common electrode formed on the organic layer.

The present invention also discloses a method for manufacturing including preparing a display apparatus having an insulating substrate, a metal film formed on a first surface of the insulating substrate, and a thin film transistor formed on a second surface of the insulating substrate, seating the display apparatus in a seating unit having an accommodating part to accommodate the display apparatus therein and a magnet provided in the accommodating part while the metal film faces the magnet, placing a substrate supporter having a magnetic substance on the display apparatus, rotating the display apparatus upside down in the state that the display apparatus and the substrate supporter are both attracted by a magnetic force to the magnet, and depositing a deposition material on the display apparatus.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is an equivalent circuit diagram illustrating a pixel of a display apparatus according to a first exemplary embodiment of the present invention.

FIG. 2 is a sectional view of the display apparatus according to the first exemplary embodiment of the present invention.

FIG. 3A, FIG. 3B, FIG. 3C, FIG. 3D, and FIG. 3E are sectional views sequentially showing a method of fabricating the display apparatus according to the first exemplary embodiment of the present invention.

FIG. 4 and FIG. 5 are a sectional view and a rear view of a display apparatus, respectively, according to a second exemplary embodiment of the present invention.

### DETAILED DESCRIPTION OF EMBODIMENTS

The invention is described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present.

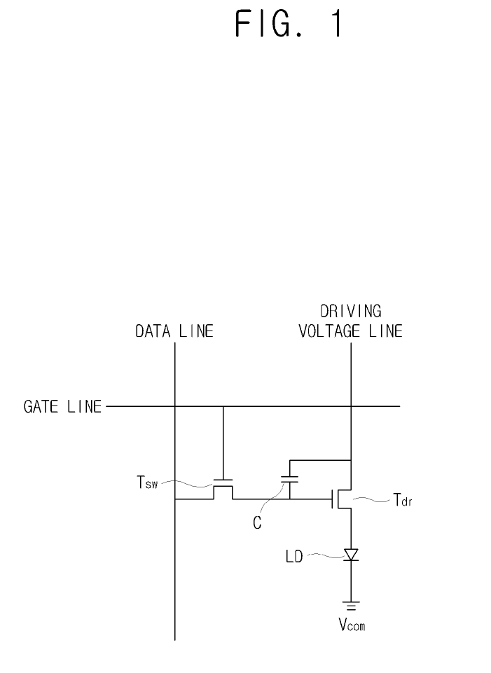

FIG. 1 is an equivalent circuit diagram of a display apparatus according to a first exemplary embodiment of the present invention.

Referring to FIG. 1, one pixel includes a plurality of signal lines. The signal lines include a gate line to transmit a scan signal, a data line to transmit a data signal, and a driving voltage line to apply a driving voltage. The data line and the driving voltage line are arranged adjacent to and in parallel with each other. Further, the gate line crosses both the data line and the driving voltage line.

Each pixel includes an organic light emitting device LD, a switching transistor Tsw, a driving transistor Tdr, and a capacitor C.

The driving transistor Tdr has a control terminal connected to the switching transistor Tsw, an input terminal connected to the driving voltage line, and an output terminal connected to the organic light emitting device LD.

The organic light emitting device LD has an anode connected to the output terminal of the driving transistor Tdr, and a cathode connected to a common voltage Vcom. The organic light emitting device LD emits light with brightness varying according to the intensity of a current from the driving transistor Tdr, thereby displaying an image. Here, the intensity of the current from the driving transistor Tdr varies according to voltage applied between the control terminal and the output terminal of the driving transistor Tdr.

The switching transistor Tsw has a control terminal connected to the gate line, an input terminal connected to the data line, and an output terminal connected to the control terminal of the driving transistor Tdr. The switching transistor Tsw transmits the data signal from the data line to the driving transistor Tdr in response to the scan signal applied to the gate line.

The capacitor C is connected between the control terminal and the input terminal of the driving transistor Tdr. The capacitor C stores and maintains the data signal to be inputted to the control terminal of the driving transistor Tdr.

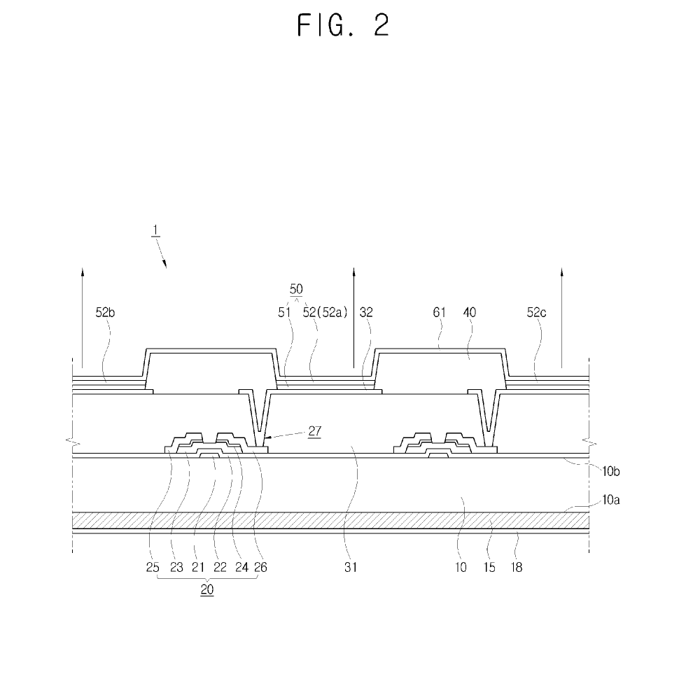

Below, the display apparatus according to the first exemplary embodiment will be described in more detail with reference to FIG. 2. In FIG. 2, a thin film transistor 20 is the driving transistor and the display apparatus is top-emission type.

The display apparatus 1 according to the first exemplary embodiment includes an insulating substrate 10, a metal film 15 formed on a first surface 10a of insulating substrate 10, and a metal passivation film 18 for protecting the metal film 15. Further, the display apparatus 1 comprises the thin film transistor 20, a passivation film 31, a pixel electrode 32, a partition wall 40, an organic layer 50, and a common electrode 61, which are formed on a second surface 10b of the insulating substrate 10.

The insulating substrate 10 includes a dielectric material such as glass, quartz, ceramic, plastic or the like. Typically, a glass substrate or a plastic substrate is used as the insulating substrate 10.

A magnetic film such as the metal film 15, is arranged on the first surface 10a of the insulating substrate 10. The metal film 15 may be formed on the entire insulating substrate 10. The metal film 15 may have a thickness of 50 μm through 1000 μm depending on a raw material of the metal film 15 and the magnetic force of a magnet 280 provided in a manufacturing apparatus 100 (to be described later) for the display apparatus but is not limited thereto. The metal film 15 includes one of iron, nickel, and cobalt, or an alloy thereof and may be formed by a sputtering method. Here, iron, nickel, and cobalt are ferromagnetic substances which have good attraction to the magnet 280 of the manufacturing apparatus 100.

The metal film 15, which is formed on the first surface 10a of the insulating substrate 10, is closely attached to the magnet 280 by the attractive force of the magnet 280 when the display apparatus 1 is turned upside down during manufacturing so as to form the organic layer 50 or/and the common electrode 61 by a thermal evaporation method. Thus, the metal film 15 may prevent the insulating substrate 10 from sagging while forming the organic layer 50 or/and the common electrode 61.

The metal passivation film 18 is arranged on the metal film 15 to protect the metal film 15. Like the passivation film 31, the metal passivation film 18 comprises silicon nitride (SiNx) or/and an organic material. In this embodiment, silicon nitride (SiNx) is formed as the metal passivation film 18 by chemical vapor deposition (CVD). When organic material is used as the metal passivation film 18, a slit coating method or a spin coating method can be used to form the metal passivation film 18.

The metal passivation film 18 is formed to prevent the metal film 15 from being damaged (e.g., corroded). The metal passivation film 18 may be formed directly after forming the metal film 15. Alternatively, the metal passivation film 18 may be formed after the organic layer 50 or/and the common electrode 61 are completed by the thermal evaporation method.

The thin film transistor 20 includes a gate electrode 21, a gate insulating film 22, a semiconductor layer 23, an ohmic contact layer 24, a source electrode 25 and a drain electrode 26.

The gate insulating film 22 may include silicon nitride (SiNx) or the like and is formed on the gate electrode 21. The gate electrode 21 branches from a gate line (not shown) and may be a single layer or a multi layer.

The semiconductor layer 23, including amorphous silicon, and the ohmic contact layer 24, including hydrogenated n+ amorphous silicon highly doped with an n-type dopant, may be formed in sequence on the gate insulating film 22 corresponding to the gate electrode 21. Here, the ohmic contact layer 24 is separated into two parts with respect to the gate electrode 21.

The source electrode 25 and the drain electrode 26 are formed on the ohmic contact layer 24 and the gate insulating layer 22. Further, the source electrode 25 and the drain electrode 26 are separated into with respect to the gate electrode 21.

In the drawing, the thin film transistor 20 includes amorphous silicon but may alternatively include polysilicon.

The passivation film 31 is formed on the source electrode 25, the drain electrode 26, and the exposed portion of the semiconductor layer 23 between the source electrode 25 and drain electrode 26. The passivation film 31 may include silicon nitride (SiNx) or/and the organic material. The passivation film 31 includes a contact hole 27 to expose the drain electrode 26.

The pixel electrode 32 is formed on the passivation film 31. The pixel electrode 32 may be an anode, and in this case, it supplies holes to the emission layer 52. The pixel electrode 32 may include a transparent conductive material such as indium tin oxide (ITO), indium zinc oxide (IZO), etc., and may be formed by sputtering. Here, the pixel electrode 32 may be patterned to have an approximately rectangular shape from a plan view.

A partition wall 40 is formed between the pixel electrodes 32. The partition wall 40 is shaped like a mesh and divides the pixel electrodes 32, thereby defining a pixel region. Further, the partition wall 40 is formed on the thin film transistor 20 and the contact hole 27. Here, the partition wall 40 prevents the source electrode 25 and the drain electrode 26 of the thin film transistor 20 from short-circuiting with the common electrode 61. The partition wall 40 may include a photosensitive material such as an acrylic resin, a polyimide resin, etc., which has heat resistance and solvent resistance and an inorganic material such as SiO₂ and TiO₂. Further, the partition wall 40 may be a double-layered structure including an organic layer and an inorganic layer. The partition wall 40 can be formed by photolithography or an inkjet method.

The organic layer 50 is formed on the pixel electrode 32 uncovered by the partition wall 40. The organic layer 50 includes the hole injecting layer 51 and the emission layer 52.

The hole injecting layer 51 includes a hole injecting material, which is a low molecular weight organic material and may be formed by the thermal evaporation method.

The emission layer 52 includes sub-layers such as a red emission layer 52a, a green emission layer 52b and a blue emission layer 52c, which are alternately formed. The emission layer 52 includes an emission material, which is a low molecular weight organic material and may be formed by the thermal evaporation method.

A hole from the pixel electrode 32 and an electron from the common electrode 61 combine into an exciton in the emission layer 52, and light is emitted while the exciton is deactivated.

The hole injecting layer 51 and the emission layer 52 of the display apparatus 1 according to the first exemplary embodiment of the present invention are formed by the thermal evaporation method in the state that the metal film 15 prevents the insulating substrate 10 from sagging, thereby making the substrate 10 flat. Therefore, the hole injecting layer 51 and the emission layer 52 may have uniform thickness regardless of positions of the insulating substrate 10. Thus, it may be possible to prevent a short-circuit between the pixel electrode 32 and the common electrode 61 in the pixel region, which occurs when the organic layer 50 is not uniformly formed due to the sagging insulating substrate 10.

The common electrode 61 is provided on the partition wall 40 and the emission layer 52. The common electrode 61 may be a cathode, and in this case, it supplies electrons to the emission layer 52.

The common electrode 61 may include a transparent conductive material such as ITO or IZO, an alloy of magnesium and silver, or an alloy of calcium and silver. The common electrode 61 may be a double-layered structure including a lower layer of a metal alloy and an upper layer of ITO or IZO. The common electrode 61 may be formed by the sputtering method. Alternatively, the common electrode 61 can be formed by the thermal evaporation method like the organic layer 50. The thickness of the common electrode 61 may vary according to the materials but should be uniform throughout the insulating substrate 10. In the case where the thickness of the common electrode 61 is not uniform, thin parts may cause an excessively large resistance, and thus a common voltage is not efficiently applied while thick parts may cause the common electrode 61 to be opaque, and thus brightness noticeably decreases while light passes through the common electrode 61.

The common electrode 61 of the display apparatus 1 according to the first exemplary embodiment of the present invention is formed in the state that the insulating substrate 10 is prevented from sagging by the metal film 15 and is flat, so that the common electrode 61 may be formed with a uniform thickness regardless of the positions of the insulating substrate 10.

Further, the display apparatus 1 may include an electron transfer layer (not shown) and an electron injecting layer (not shown) between the emission layer 52 and the common electrode 61. Also, the display apparatus 1 may include an additional passivation film for protecting the common electrode 61, and an encapsulating member (not shown) to prevent water and air permeating into the organic layer 50. Here, the encapsulating member may include an encapsulating resin and/or an encapsulating can.

In the display apparatus 1 with this configuration according to the first exemplary embodiment, when the insulating substrate 10 is turned upside down to form the organic layer 50 or/and the common electrode 61, the magnetic force of the magnet 280 attracts the metal film 15. As the metal film 15 is attached to the magnet 280, the insulating substrate 10 may be prevented from sagging while the organic layer 50 or/and the common electrode 61 are formed, thereby preventing the insulating substrate 10 from being damaged. Further, the pixel electrode 32 and the common electrode 61 may be prevented from being short-circuited in the pixel region where the organic layer 50 is not uniformly formed by the sagged insulating substrate 10, and thus the common electrode 61 is uniformly formed, thereby enhancing the performance of the display apparatus 1.

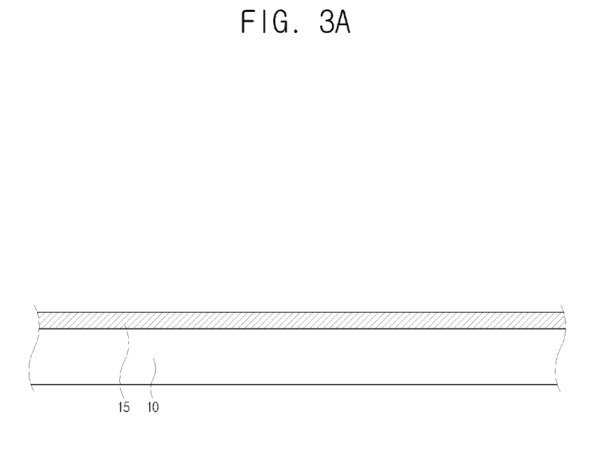

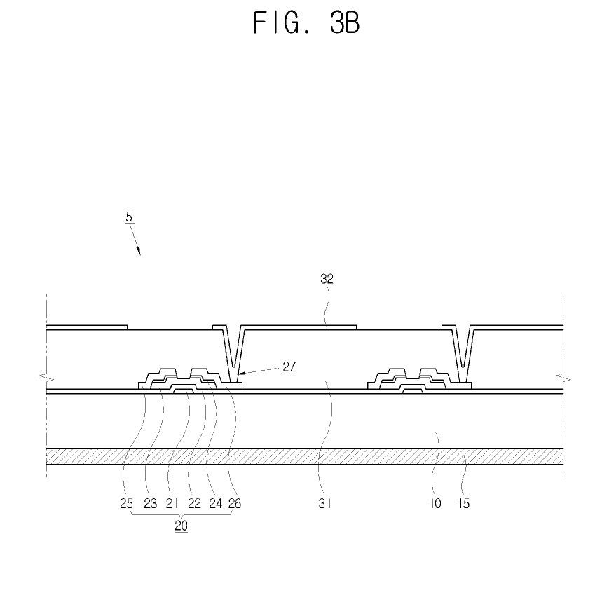

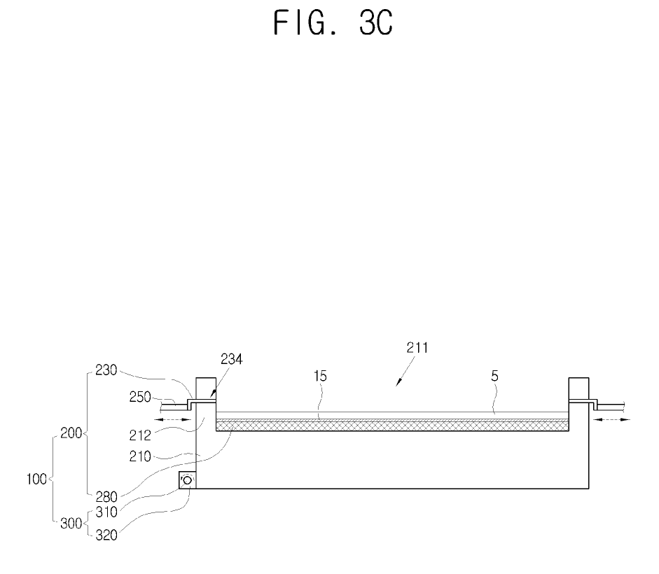

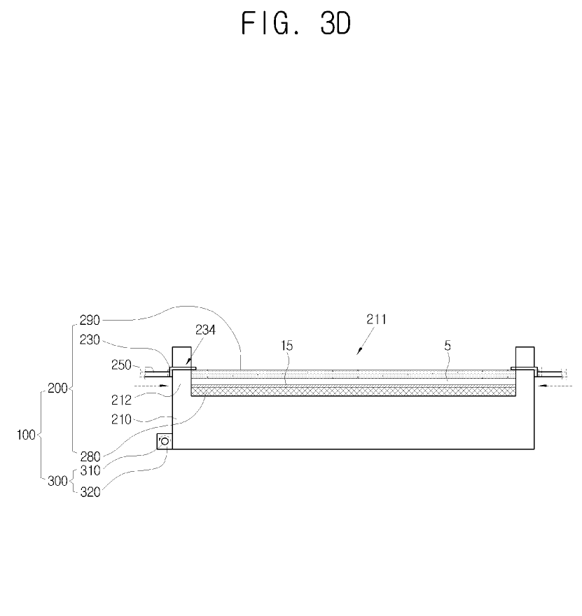

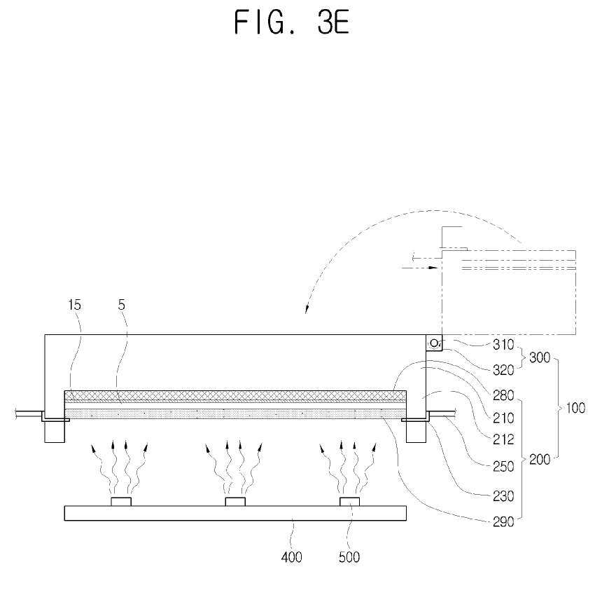

Below, a method of manufacturing the display apparatus according to the first exemplary embodiment of the present invention will be described with reference to FIG. 3A, FIG. 3B, FIG. 3C, FIGS. 3D, and 3E.

Before describing the method of fabricating the display apparatus according to the first exemplary embodiment, the manufacturing apparatus 100 used herein will be described with reference to FIG. 3D and FIG. 3E.

The manufacturing apparatus 100 for the display apparatus includes a seating unit 200 and a rotating unit 300.

The seating unit 200 includes a base 210, an accommodating part 211 formed on the base 210, a supporting wall 212 upwardly extended from the edge of the accommodating part 211, a holder 230 penetrating the supporting wall 212, a mover 250 moving the holder 230, the magnet 280, which may be stationary in the accommodating part 211, and a shadow mask 290 including a material to be attracted by the magnet 280 and used as a detachable substrate supporter.

The accommodating part 211 flatly formed on the base 210 accommodates a display substrate 5 during manufacturing.

The supporting wall 212 includes a plurality of through holes 234 in the center thereof. The supporting wall 212 supports the holder 230 moving between a locking position and a releasing position through the through hole 234.

The holder 230 holds the display substrate 5 and the shadow mask 290 after the display substrate 5 and the shadow mask 290 are sequentially accommodated in the accommodating part 211. The holder 230 is connected to the mover 250, and moves between the locking position and the releasing position as the mover 250 moves forward and backward. Here, the mover 250 may be a known means such as a motor.

The magnet 280, which corresponds to the shape of the accommodating part 211, is closely attached to the base 210. Therefore, the display substrate 5 may be closely attached to the magnet 280 when accommodated in the accommodating part 211 during manufacturing. The magnetic force of the magnet 280 may range from 20,000 gauss to 70,000 gauss to provide an adequate attractive force with the metal film 15 and the shadow mask 290. Here, the magnet may be a permanent magnet or an electromagnet. In this embodiment, the magnet is implemented by the electromagnet, and the manufacturing apparatus 100 further includes a current supply (not shown) to supply a current to the electromagnet for generating the magnetic force.

The shadow mask 290 is provided on the display substrate 5, which contacts the magnet 280. The shadow mask 290 is used as the substrate supporter and includes chrome alloy steel, nickel alloy steel, etc., which are attracted by the magnetic force of the magnet 280. The shadow mask 290 includes a deposition hole (not shown), so that a deposition material evaporated from a source 500 may pass through the deposition hole and be deposited on the display substrate 5. Further, the shadow mask 290 supports the display substrate 5 by the attraction with the magnet 280 when the seating unit 200 is turned upside down, so that the center of the rotated insulating substrate 10 may be prevented from sagging. Thus, the shadow mask 290 and the holder 230 support the display substrate 5, thereby preventing the insulating substrate 10 of the display substrate 5 from sagging.

Further, the rotating unit 300 is provided at one end of the seating unit 200.

The rotating unit 300 includes a rotating shaft 310 connected to an external power source (not shown) and rotated by the power source, and a rotating body 320 surrounding the rotating shaft 310 and rotating the seating unit 200 upside down by the rotational force of the rotating shaft 310.

The rotating unit 300 operates to rotate the seating unit 200 upside down, wherein the display substrate 5 is seated in the seating unit 200. Thus, the display substrate 5 may be rotated so that the parts thereof needing the deposition face down. Alternatively, the rotating unit 300 may be connected to opposite ends of a short or long side of the seating unit 200 as long as the seating unit 200 is rotated upside down.

Below, the method of manufacturing the display apparatus according to the first exemplary embodiment of the present invention will be described.

As shown in FIG. 3A and FIG. 3B, the metal film 15 is formed on a first surface of the insulating substrate 10, and the pixel electrode 32 is formed on the second surface of the insulating substrate 10.

In more detail, the metal film 15 is formed to have a thickness of 50 μm through 1000 μm on the entire first surface of the insulating substrate 10. The metal film 15 includes one of ferromagnetic substances such as iron, nickel, and cobalt, or alloy thereof, and may be formed by the sputtering method.

Then, as shown in FIG. 3B, the thin film transistor 20, the passivation film 31, and the pixel electrode 32 are formed on the second surface of the insulating substrate 10, thereby preparing the display substrate 5.

The thin film transistor 20 includes a channel made of amorphous silicon and can be manufactured by a known method.

After forming the thin film transistor 20, the passivation film 31 is formed on the thin film transistor 20. The passivation film 31 can be formed by CVD when it includes silicon nitride. Then, the passivation film 31 is photolithographed to provide the contact hole 27 exposing the drain electrode 26. After forming the contact hole 27, the pixel electrode 32 is formed to be connected to the drain electrode 26 through the contact hole 27. Here, the pixel electrode 32 can be formed by depositing ITO by a sputtering method and patterning it.

Then, as shown in FIG. 3C, the display substrate 5 is seated in the accommodating part 211 of the manufacturing apparatus 100, so that the metal film 15 of the display substrate 5 faces the magnet 280 of the accommodating part 211. At this time, the holder 230 is in the releasing position.

As shown in FIG. 3D, the shadow mask 290 is seated on the display substrate 5. Then, the holder 230 is moved to the locking position by the mover 250, thereby holding the display substrate 5 and the shadow mask 290. In this process, the magnet 280 receives electric current from the current supply (not shown) and generates magnetic force. Thus, the magnetic force of the magnet 280 causes the attraction between the magnet 280 and the metal film 15 and between the magnet 280 and the shadow mask 290.

As shown in FIG. 3E, the display substrate 5 is turned upside down, and then the deposition material is deposited on the display substrate 5.

To turn the display substrate 5 upside down, the rotating shaft 310 of the rotating unit 300 connected to one end of the seating unit 200 is rotated by the external power source (not shown). Thus, the rotational force of the rotating shaft 310 is transferred to the rotating body 320 surrounding the rotating shaft 310, so that the rotating unit 300 rotates the seating unit 200 upside down to be disposed above and face to a deposition source unit 400.

Then, to deposit the deposition material on the display substrate 5 by the thermal evaporation method, the deposition material is evaporated from a plurality of sources 500 provided on the deposition source unit 400 and then deposited on the display substrate 5 through the deposition hole. By changing the deposition source 500 or/and the shadow mask 290, the hole injecting layer 51 and the emission layer 52 can be deposited on the pixel electrode 32. Likewise, the common electrode 61 can be deposited as necessary on the organic layer 50.

In the rotating and deposition processes for the display substrate 5, the rotated insulating substrate 10 may sag due to gravity. However, the attraction between the magnet 280 and the shadow mask 290 may decrease the sag of the insulating substrate 10, and the attraction between the magnet 280 and the metal film 15 may also decrease the sag of the insulating substrate 10.

After the deposition process, the display substrate 5 is removed from the manufacturing apparatus 100, and the metal passivation film 18 may be formed on the metal film 15 by CVD at a low temperature, thereby completing the display apparatus 1 according to the first exemplary embodiment.

Alternatively, after forming the metal film 15, the metal passivation film 18 can be formed just before forming the thin film transistor 20. In this case, the display substrate 5 can be manufactured by CVD at a high temperature before forming the organic layer 50 which is susceptive to heat, thereby enhancing a manufacturing efficiency thereof.

In the method of manufacturing the display apparatus according to the first exemplary embodiment of the present invention, the insulating substrate 10 of the display substrate 5 may be prevented from sagging. Further, the insulating substrate 10 is maintained substantially flat, so that the insulating substrate 10 may be prevented from being damaged. Further, it is possible to avoid producing a defective display apparatus where the pixel electrode 32 and the common electrode 61 short-circuit in the pixel region due to the organic layer 50 not being uniformly formed on a sagged insulating substrate. Also, the common electrode 61 is uniformly formed, thereby enhancing the performance of the display apparatus 1.

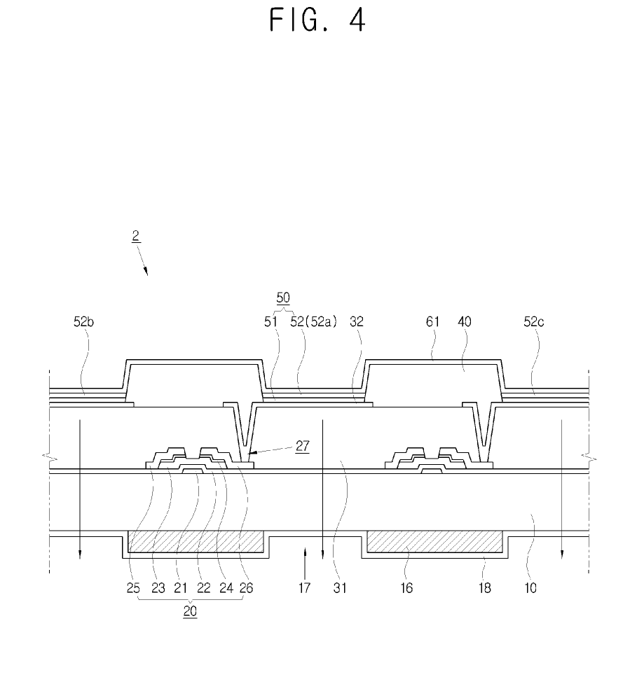

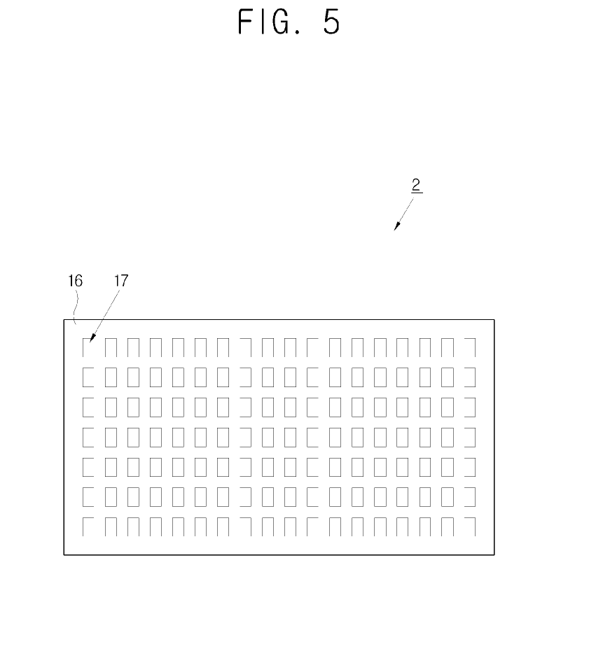

Below, a display apparatus according to a second exemplary embodiment of the present invention will be described with reference to FIG. 4 and FIG. 5 while emphasizing difference from that of the first exemplary embodiment. FIG. 4 and FIG. 5 are a sectional view and a rear view, respectively, of a display apparatuses according to a second exemplary embodiment of the present invention.

A display apparatus 2 according to the second exemplary embodiment of the present invention is a bottom-emission type. A metal film 16 is formed with an opening 17 at a position corresponding to the pixel region, thereby allowing emission of light to that passes through the insulating substrate 10. The pixel electrode 32 includes a transparent metal or a transparent conductive material, and the common electrode 61 may include an opaque metal or an opaque conductive material.

Further, a method of manufacturing the display apparatus according to the second exemplary embodiment is similar to that of the first exemplary embodiment except that a mask or the like is used in forming the opening 17 when the metal film 16 is formed by the sputtering method.

Thus, the display apparatus 2 and its manufacturing method according to the second exemplary embodiment of the present invention can obtain the same effect as that of the first exemplary embodiment.

In the foregoing embodiment, an OLED is exemplarily described as the display apparatuses 1 and 2. However, the present invention can be applied to various display apparatuses, such as an LCD, as long as a certain material is deposited thereto by the thermal evaporation method.

As described above, the present invention provides a display apparatus with a structure that may be used to effectively prevent an insulating substrate from sagging in a manufacturing process and a method of manufacturing the same.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A display apparatus, comprising:
an insulating substrate;
a metal film arranged on a first surface of the insulating substrate;
a thin film transistor arranged on a second surface of the insulating substrate;
a first passivation film arranged on the thin film transistor;
a pixel electrode arranged on the first passivation film, electrically connected with the thin film transistor, and forming a pixel region;
an organic layer arranged on the pixel electrode; and
a common electrode arranged on the organic layer.

2. The display apparatus of claim 1, further comprising a partition wall arranged on the first passivation film between pixel electrodes.

3. The display apparatus of claim 1, wherein the insulating substrate comprises one of a glass substrate and a plastic substrate.

4. The display apparatus of claim 1, wherein the organic layer comprises a hole injecting layer and an emission layer.

5. The display apparatus of claim 4, wherein the metal film comprises at least one of iron, nickel, and cobalt.

6. The display apparatus of claim 5, further comprising a second passivation film arranged on the metal film.

7. The display apparatus of claim 6, wherein the pixel electrode comprises a reflective layer, and
the metal film completely covers the first surface of the insulating substrate.

8. The display apparatus of claim 6, wherein
the pixel electrode comprises a transparent conductive material, and the metal film comprises an opening corresponding to the pixel region.

9. A method for manufacturing a display device, comprising:
providing a display substrate comprising an insulating substrate, a metal film formed on a first surface of the insulating substrate and comprising a magnetic substance, and a thin film transistor formed on a second surface of the insulating substrate;
arranging the display substrate in a seating unit comprising an accommodating part to accommodate the display apparatus therein and a magnet provided in the accommodating part, the metal film facing the magnet;
placing a substrate supporter on the display substrate, the substrate supporter comprising a magnetic material;
rotating the display substrate upside down in the state that the display substrate and the substrate supporter are both attracted by a magnetic force to the magnet; and
depositing a material on the display substrate.

10. The method of claim 9, wherein the display substrate further comprises a passivation film formed on the metal film.

11. The method of claim 9, further comprising:
forming a passivation film on the metal film after the depositing.

12. The method of claim 9, wherein the depositing is performed while the display substrate is flat.

13. The method of claim 9, wherein the depositing is performed while the substrate supporter supports the display substrate by a magnetic force between the substrate supporter and the magnet.

14. The method of claim 9, wherein the depositing is performed by a thermal evaporation method.

15. The method of claim 14, wherein the insulating substrate comprises one of a glass substrate and a plastic substrate.

16. The method of claim 14, wherein the organic layer comprises a hole injecting layer and an emission layer.

17. The method of claim 16, wherein the metal film comprises at least one of iron, nickel, and cobalt.

18. The method of claim 17, wherein the metal film completely covers the insulating substrate.

19. The method of claim 17, wherein the metal film comprises regularly arranged openings.

20. The method of claim 17, wherein the magnet has a magnetic force of 20,000 gauss through 70,000 gauss.

21. The method of claim 17, wherein the substrate supporter comprises a shadow mask.
